(19) United States
(12) Patent Application Publication
(10) Pub. No.: US 2010/0133580 A1
(43) Pub. Date: Jun. 3, 2010

(54) LIGHT EMITTING DIODE PACKAGE STRUCTURE AND CONDUCTIVE STRUCTURE AND MANUFACTURING METHOD THEREOF

(75) Inventor: Ke-Hao Pan, Taipei City (TW)

Correspondence Address: QUINTERO LAW OFFICE, PC, 615 Hampton Dr, Suite A202, Venice, CA, 90291, US

(73) Assignee: EVERLIGHT ELECTRONICS CO., LTD., Taipei (TW)

(21) Appl. No.: 12/696,984

(22) Filed: Jan. 29, 2010

Related U.S. Application Data
(63) Continuation-in-part of application No. 12/003,835, filed on Jan. 2, 2008.

(30) Foreign Application Priority Data
Nov. 25, 2009 (TW) TW98140063

(51) Int. Cl. H01L 33/00; H01L 31/00

(52) U.S. Cl. 257/99; 438/26; 257/E33.001; 257/E31.001

(57) ABSTRACT

A light emitting diode package structure includes a frame, a light emitting diode chip electrically coupled to the frame, an upper packing portion covering the light emitting diode chip on the frame, and a lower packing portion circumferentially disposed on the frame for fixation and next to the upper packing portion. Lights from the light emitting diode chip are outwardly emitted through the upper packing portion. The lower packing portion is extended from and partially covered by the upper packing portion.

### CROSS REFERENCE TO RELATED APPLICATIONS

This application is a Continuation-In-Part of pending U.S. patent application Ser. No. 12/003,835, filed Jan. 2, 2008 and entitled “STRUCTURE OF LIGHT EMITTED DIODE PACKAGE”.

This Application claims priority of Taiwan Patent Application No. 098140063, filed on Nov. 25, 2009, the entirety of which is incorporated by reference herein.

### BACKGROUND OF THE INVENTION

1. Field of the Invention

The present invention relates to a light emitting diode package structure, and in particular, relates to a light emitting diode package structure provided with a conductive structure and a manufacturing method thereof.

2. Description of the Related Art

In general, epoxy resin is used for packing conventional cap-type light emitting diodes. In particular, the epoxy resin applied in the high power cap-type light emitting diodes (with blue-white light) is carbonized and faded when ultraviolet light is radiated and a heat is generated. In some cases, a full silicone packing is therefore applied in the high power cap-type light emitting diodes for reducing carbonization and fading; however, the cost for the full silicone packing process is high.

In addition, because the silicone is not as hard as the epoxy resin and is easily damaged by an external force, a plastic injection molding is generally applied on a frame of the light emitting diodes to stabilize the whole structure thereof. However, although the described carbonization and fading can be prohibited by the combination of the injection molding and the full silicone packing, the plastic is a low heat conductive material and cannot provide sufficient heat dissipation for the light emitting diode. Another conventional example discloses that a frame of a high power lamp light emitting diode (lamp LED) is formed by a heat-dissipative plastic material formation technique and packed by an anti-fading material thereon, but the heat dissipation efficiency and reliability thereof cannot be improved.

In view of these problems above, a high power light emitting diode capable of providing advanced high dissipation efficiency should be developed.

### BRIEF SUMMARY OF THE INVENTION

The invention provides a different light emitting diode package structure. The light emitting diode package structure comprises a frame, a light emitting diode chip, an upper packing portion and a lower packing portion. The light emitting diode chip is electrically coupled to the frame. The upper packing portion is utilized to cover the light emitting diode chip on the frame, wherein a light radiated from the light emitting diode chip is outwardly emitted through the upper packing portion. The lower packing portion is circumferentially disposed on the frame and disposed next to the upper packing portion to secure the frame, wherein the lower packing portion is extended from and partially covered by the upper packing portion.

In one feature of the invention, the frame comprises a first leg and a second leg, the light emitting diode chip is disposed on the first leg of the frame and electrically coupled to the second leg of the frame, the upper packing portion is utilized to cover the light emitting diode chip disposed on the first leg and the second leg of the frame, and the lower packing portion is fixed at the first and second legs of the frame.

In one feature of the invention, the light emitting diode package structure further comprises a supporting portion disposed on an end of the first leg of the frame, wherein the light emitting diode chip is disposed on the supporting portion. The end of the first leg of the frame is fixed at the supporting portion by a silver glue layer, and an end of the second leg of the frame is electrically coupled to the light emitting diode chip by a lead wire. The end of the second leg of the frame is electrically coupled to the light emitting diode chip by an eutectic reaction.

In one feature of the invention, the first and second legs of the frame are downwardly extended and arranged in parallel.

In one feature of the invention, the upper packing portion and the lower packing portion are partially overlapped to each other.

In one feature of the invention, the upper packing portion comprises an anti-fading material, and the lower packing portion comprises a heat-dissipative material.

In one feature of the invention, the anti-fading material is selected from the group of epoxy, methyl rubber, methyl resin, benzene ring resin, organic denature silicon and the combination thereof.

In one feature of the invention, the heat-dissipative material is selected from the group of poly para-phenylenediacyl para-phenylenediamine, high temperature nylon, liquid crystalline resin, Polyetheretherketone, resin containing silicon, polyamide-imide resin, ceramic and the combination thereof.

In one feature of the invention, the lower packing portion comprises at least one extension oppositely extended relative to the upper packing portion.

In one feature of the invention, the light emitting diode package structure further comprises a heat-dissipative element, and the lower packing portion comprises at least one extension connected to the heat-dissipative element, such that heat generated from the light emitting diode chip is transferred to the heat-dissipative element via the upper packing portion and the at least one extension of the lower packing portion.

In one feature of the invention, the lower packing portion is integrally formed with the frame. The lower packing portion substantially comprises a C-shaped structure.

Another embodiment of the invention provides a conductive structure utilized to dissipate heat generated from a light emitting diode chip. The conductive structure comprises an upper packing portion and a lower packing portion. The upper packing portion is utilized to cover the light emitting diode chip. The lower packing portion is disposed next to the upper packing portion, wherein the light emitting diode chip is electrically coupled to a frame, such that heat generated from the light emitting diode chip is transferred to the lower packing portion via the frame.

In one feature of the invention, the conductive structure further comprises a heat-dissipative element, and the lower packing portion comprises at least one extension connected to the heat-dissipative element, such that heat generated from the light emitting diode chip is transferred to the heat-dissipative element via the upper packing portion and at least one extension of the lower packing portion.

Another embodiment of the invention provides a method for manufacturing a light emitting diode package structure. The method comprises the steps of: providing a frame comprising a first leg and a second leg; providing a light emitting diode chip disposed on the first leg of the frame and electrically coupled to the second leg of the frame; utilizing a first heat-dissipative unit to cover and secure the first and second legs of the frame; and utilizing an anti-fading unit to cover the light emitting diode chip on the frame and to partially cover the first heat-dissipative unit, such that light emitting from the light emitting diode chip is outwardly radiated via the anti-fading unit, and heat generated from the light emitting diode chip is transferred to the first heat-dissipative unit via the anti-fading unit.

In one feature of the invention, the method further provides a lead wire electrically coupled between the light emitting diode chip disposed on the first leg of the frame and the second leg of the frame.

In one feature of the invention, the method further provides a second heat-dissipative unit, and the first heat-dissipative unit further comprises at least one extension connected to the second heat-dissipative unit, such that heat generated from the light emitting diode chip is transferred to the second heat-dissipative element via the anti-fading unit and the first heat-dissipative unit.

Another embodiment of the invention provides a light emitting diode package structure. The light emitting diode package structure comprises a frame, a light emitting diode chip, a lower packing portion and an upper packing portion. The light emitting diode chip is electrically coupled to the frame. The lower packing portion is disposed on the frame, comprising a body and at least one extension connected to the body. The upper packing portion is utilized to cover the light emitting diode chip, to fully cover the body of the lower packing portion, and to partially cover at least one extension of the lower packing portion.

In one feature of the invention, the upper packing portion comprises a cylindrical part, a semi-sphere part and a conical part disposed between the cylindrical part and the semi-sphere part.

In one feature of the invention, the upper packing portion comprises a cylindrical part and a semi-sphere part, and the diameter of the semi-sphere part is less than that of the cylindrical part.

In one feature of the invention, the upper packing portion comprises a first cylindrical part, a semi-sphere part and a second cylindrical part disposed between the first cylindrical part and the semi-sphere part.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a perspective view of a light emitting diode package structure according to a first embodiment of the invention;

FIGS. 2A to 2D are schematic views showing the formation of the light emitting diode package structure in each step of the manufacturing process, wherein FIG. 2A is a schematic view of a frame, FIG. 2B is a schematic view of a lower packing portion circumferentially disposed on the frame for fixation, and FIG. 2C is a schematic view of an upper packing portion utilized to cover a light emitting diode chip and to partially cover the lower packing portion, and FIG. 2D is a sectional view of the light emitting diode package structure of FIG. 1;

FIG. 3A is a perspective view of a light emitting diode package structure according to a second embodiment of the invention;

FIG. 3B is a sectional view of the light emitting diode package structure of FIG. 3A;

FIG. 4A is a perspective view of a light emitting diode package structure according to a third embodiment of the invention;

FIG. 4B is a sectional view of the light emitting diode package structure of FIG. 4A;

FIG. 5 is a perspective view of a light emitting diode package structure according to a fourth embodiment of the invention;

FIGS. 6A to 6C are schematic views showing the formation of the light emitting diode package structure of the fourth embodiment in each step of the manufacturing process;

FIG. 7 is a perspective view of the light emitting diode package structure according to the fourth embodiment of the invention;

FIG. 8 is a schematic view of a lower packing portion;

FIG. 9 is a schematic view of another lower packing portion;

FIG. 10A is a perspective view of a light emitting diode package structure according to a fifth embodiment of the invention;

FIG. 10B is a side view of the light emitting diode package structure of FIG. 10A;

FIG. 10C is a sectional view of the light emitting diode package structure of FIG. 10A;

FIG. 11A is a perspective view of a light emitting diode package structure according to a sixth embodiment of the invention;

FIG. 11B is a side view of the light emitting diode package structure of FIG. 11A;

FIG. 11C is a sectional view of the light emitting diode package structure of FIG. 11A;

FIG. 12A is a perspective view of a light emitting diode package structure according to a seventh embodiment of the invention;

FIG. 12B is a side view of the light emitting diode package structure of FIG. 12A; and

FIG. 12C is a sectional view of the light emitting diode package structure of FIG. 12A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

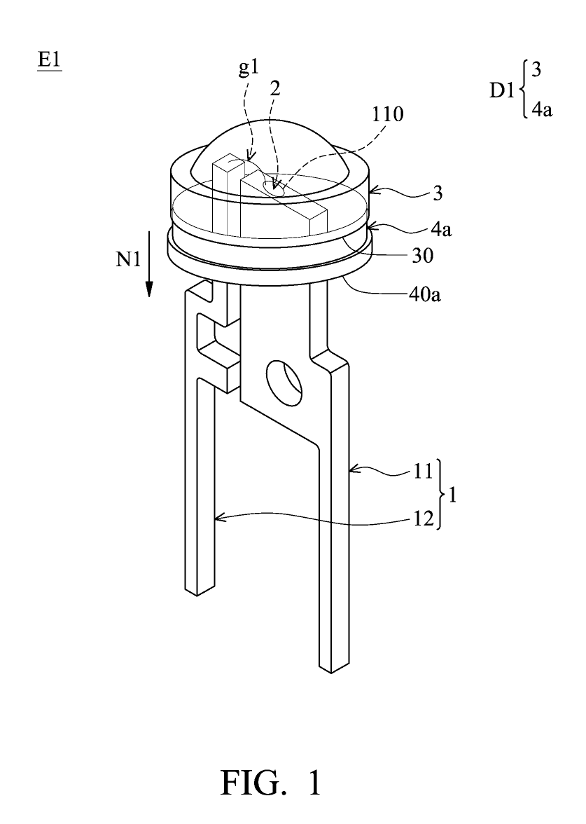

FIG. 1 is a perspective view of a light emitting diode package structure E1 and a conductive structure D1 thereof according to a first embodiment.

The light emitting diode package structure E1 comprises a frame 1, a light emitting diode chip 2, an upper packing portion 3 having a sidewall 30, a lower packing portion 4a having a sidewall 40a, a supporting portion 110 and a lead wire g1, wherein the upper packing portion 3 and the lower packing portion 4a constitute the conductive structure D1. In this embodiment, the frame 1 is made of metallic material.

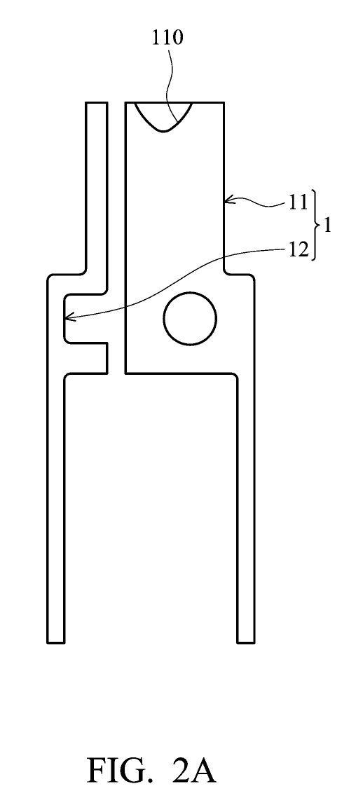

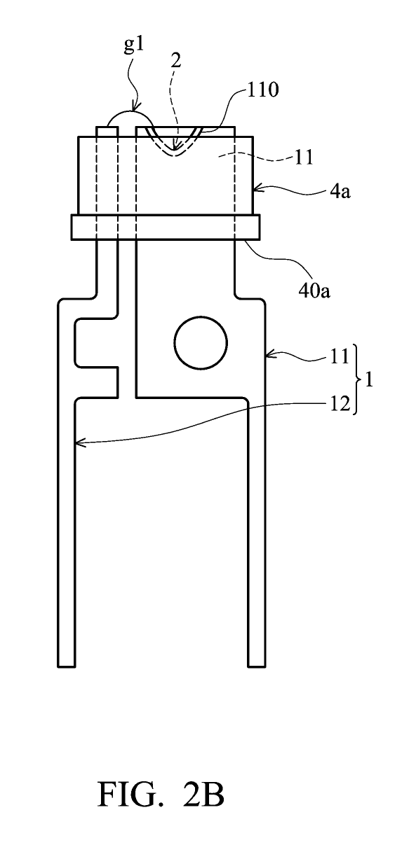

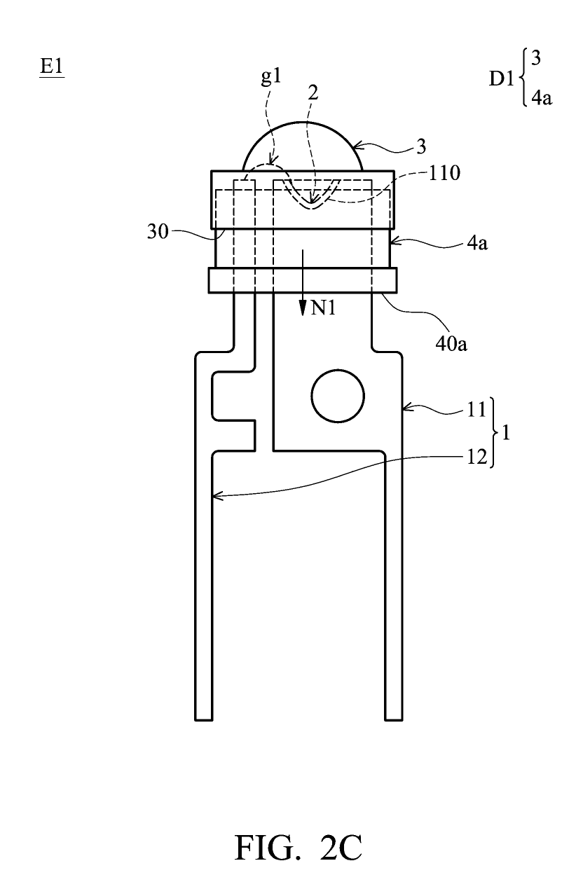

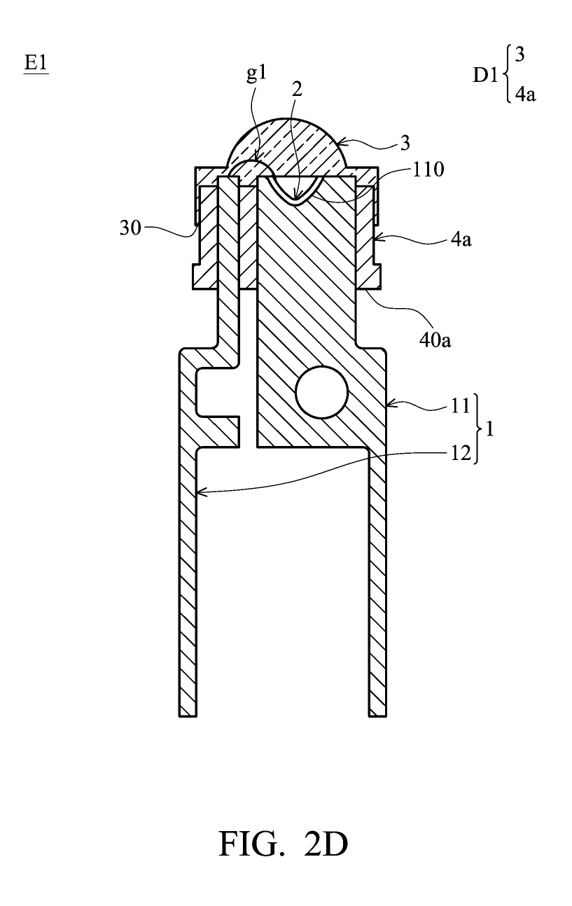

Referring to FIGS. 2A to 2D and FIG. 1 simultaneously, FIGS. 2A to 2D are schematic views showing the formation of the light emitting diode package structure E1 in each step of the manufacturing process, wherein FIG. 2A is a schematic view of the frame 1, FIG. 2B is a schematic view of the lower packing portion 4a circumferentially disposed on the frame 1 for fixation, and FIG. 2C is a schematic view of the upper packing portion 3 utilized to cover the light emitting diode chip 2 and to partially cover the lower packing portion 4a, and FIG. 2D is a sectional view of the light emitting diode package structure E1 of FIG. 1

In FIG. 2A, the frame 1 comprises a first leg 11 and a second leg 12, wherein the first and second legs 11 and 12 are downwardly extended, spaced and arranged in parallel. One end of the first leg 11 of the frame 1 is fixed at the supporting portion 110 by silver glue layer. The light emitting diode chip 2 is disposed on the supporting portion 110 and electrically coupled to one end of the second leg 12 of the frame 1 via the lead wire g1 (e.g., a metallic wire). However, the electrical connection between the light emitting diode chip 2 and the second leg 12 of the frame 1 is not limited thereto, the electrical connection of the light emitting diode chip 2 and the second leg 12 of the frame 1 can be done by an eutectic reaction other than the lead wire g1.

In the manufacturing process, prior to utilizing the upper packing portion 3 to cover the light emitting diode chip 2, the lower packing portion 4a is circumferentially disposed on the frame 1. Then, the upper packing portion 3 is partially disposed on the lower packing portion 4a, i.e., the upper packing portion 3 and the lower packing portion 4a are partially overlapped to each other, or it may be described that the lower packing portion 4a is outwardly extended from the upper packing portion 3, and the upper packing portion 3 partially covers the lower packing portion 4a.

In FIGS. 2B and 2D, the lower packing portion 4a is circumferentially fixed at the first and second legs 11 and 12 of the frame 1. It is thus that the relative relationship and structural stability of the first and second legs 11 and 12 of the frame 1 can be increased by covering the lower packing portion 4a thereon. In this embodiment, the lower packing portion 4a made of heat-dissipative material is integrally formed with the first and second legs 11 and 12 of the frame 1 by an injection molding, and the heat-dissipative material can be selected from the group of poly para-phenylenediacyl para-phenylenediamine, high temperature nylon, liquid crystalline resin, Polyetheretherketone, resin containing silicon, polyamide-imide resin, ceramic and the combination thereof.

In FIGS. 2B and 2D, the light emitting diode chip 2 disposed on the first leg 11 of the frame 1, the second leg 12 of the frame 1, and the lead wire g1 electrically coupled between the second leg 12 of the frame 1 and the light emitting diode chip 2 are simultaneously covered by the upper packing portion 3, or it may be described that the upper packing portion 3 covers the light emitting diode chip 2 on the frame 1, and also the upper packing portion 3 is disposed next to and partially covers the lower packing portion 4a. A dome-like structure is formed on the injected upper packing portion 3. A light radiated from the light emitting diode chip 2 is outwardly emitted through the upper packing portion 3. In this embodiment, the upper packing portion 3 is made of an anti-ultraviolet material (e.g., silicone) or an anti-fading material selected from the group of epoxy, methyl rubber, methyl resin, benzene ring resin, organic denature silicon and the combination thereof.

Note that there is no clearance or gap formed between the molded assembled structure of the upper packing portion 3 and the lower packing portion 4a, i.e., the light emitting diode chip 2 disposed on the first leg 11 of the frame 1 is fully covered by the upper packing portion 3. Thus, the light radiated from the light emitting diode chip 2 is outwardly emitted through the upper packing portion 3, and heat generated from the light emitting diode chip 2 is transferred from the upper packing portion 3 to the lower packing portion 4a. That is, the heat generated from the light emitting diode chip 2 is transmitted along a predetermined direction N1 for heat dissipation.

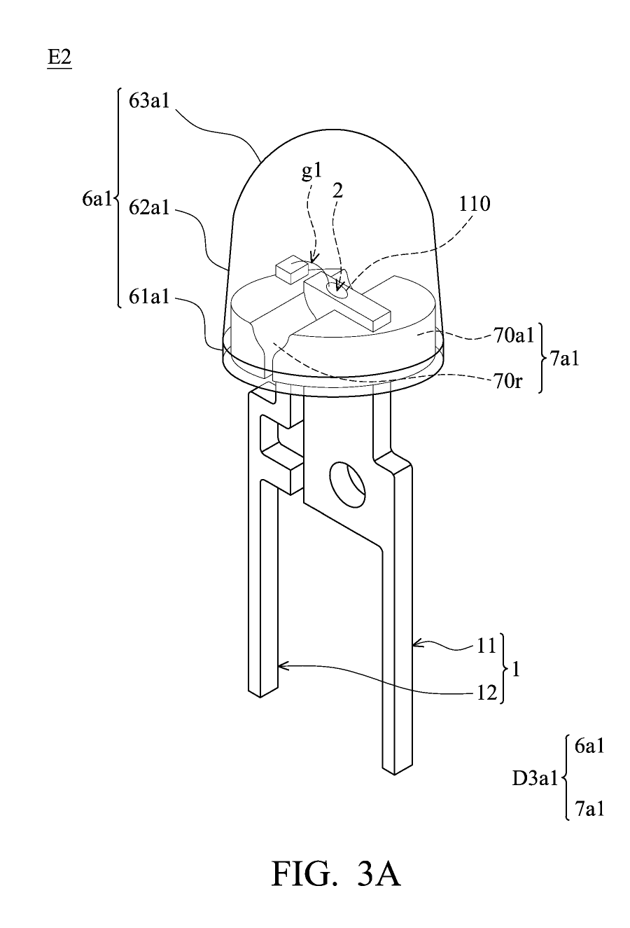

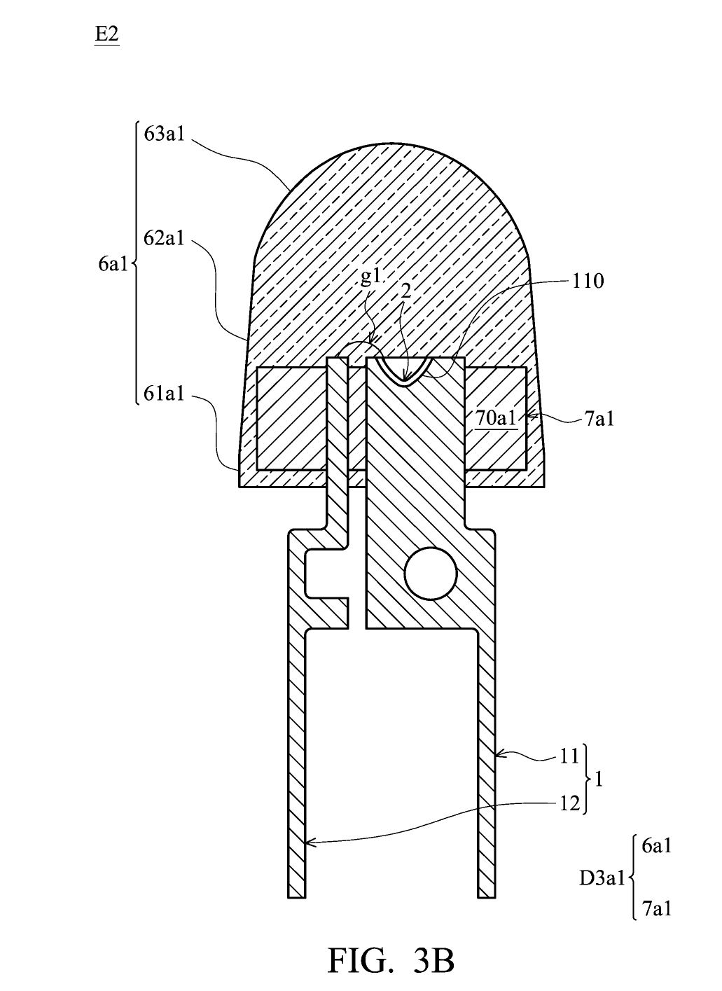

FIG. 3A is a perspective view of a light emitting diode package structure E2 according to a second embodiment, and FIG. 3B is a sectional view of the light emitting diode package structure E2 of FIG. 3A along a longitudinal direction (i.e., an extension direction of the frame 1) thereof.

In FIGS. 3A and 3B, the light emitting diode package structure E2 comprises a frame 1, a light emitting diode chip 2, an upper packing portion 6a1 and a lower packing portion 7a1, wherein the upper packing portion 6a1 and the lower packing portion 7a1 constitute a conductive structure D3a1. The frame 1, the light emitting diode chip 2 and the lead wire g1 are the same as those described in the first embodiment, and thus their description and relative relationship therebetween are not repeated here.

In the manufacturing process, the lower packing portion 7a1 is first to be disposed on the frame 1, and then the upper packing portion 6a1 fully covers the light emitting diode chip 2, the lead wire g1 and the lower packing portion 7a1.

The lower packing portion 7a1 is circumferentially disposed on the first and second legs 11 and 12 of the frame 1 by an injection molding, and the light emitting diode chip 2 is exposed by one surface of the lower packing portion 7a1. The lower packing portion 7a1 comprises a cylindrical body 70a1 and a pair of two recesses 70r which are disposed on the cylindrical body 70a1 and located at both sides of the light emitting diode chip 2. It is thus that the relative relationship and structural stability of the first and second legs 11 and 12 of the frame 1 can be increased by covering the lower packing portion 7a1 thereon.

The upper packing portion 6a1, formed by an injection molding, is utilized to cover the light emitting diode chip 2 and the lead wire g1 and to fully cover the cylindrical body 70a1 of the lower packing portion 7a1. The upper packing portion 6a1 comprises a cylindrical part 61a1, a semi-sphere part 63a1 and a conical part 62a1 disposed between the cylindrical part 61a1 and the semi-sphere part 63a1.

Note that there is no clearance or gap formed between the molded assembled structure of the upper packing portion 6a1 and the lower packing portion 7a1, i.e., the light emitting diode chip 2 disposed on the first leg 11 of the frame 1 is fully covered by the upper packing portion 6a1 and the lower packing portion 7a1. Thus, the light radiated from the light emitting diode chip 2 is outwardly emitted through the upper packing portion 6a1, and heat generated from the light emitting diode chip 2 is transferred from the frame 1 to the lower packing portion 7a1.

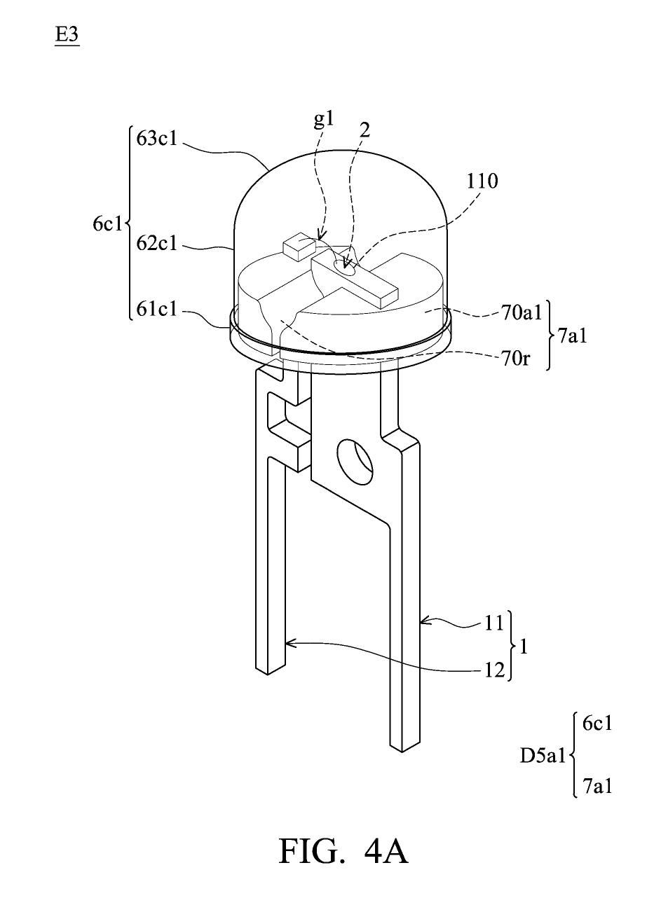

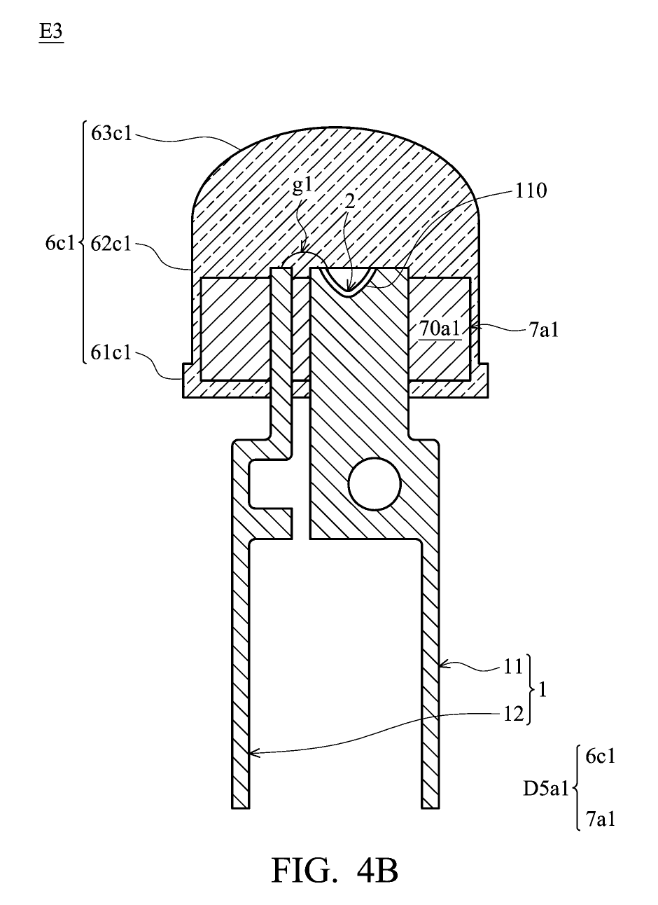

FIG. 4A is a perspective view of a light emitting diode package structure E3 according to a third embodiment, and FIG. 4B is a sectional view of the light emitting diode package structure E3 of FIG. 4A along a longitudinal direction (i.e., an extension direction of the frame 1) thereof.

In FIGS. 4A and 4B, the light emitting diode package structure E3 comprises a frame 1, a light emitting diode chip 2, an upper packing portion 6c1 and a lower packing portion 7a1, wherein the upper packing portion 6c1 and the lower packing portion 7a1 constitute a conductive structure D5c1. The frame 1, the light emitting diode chip 2, the lead wire g1 and the lower packing portion 7a1 are the same as those described in the second embodiment, and thus their description and relative relationship therebetween are not repeated here.

The light emitting diode package structure E3 of the third embodiment differs from the light emitting diode package structure E2 of the second embodiment in that the structure of the upper packing portion 6c1 is formed by a first cylindrical part 61c1, a second cylindrical part 62c1 and a semi-sphere part 63c1, wherein the second cylindrical part 62c1 is formed between the first cylindrical part 61c1 and the semi-sphere part 63c1, and the first cylindrical part 61c1 has a diameter greater than that of the second cylindrical part 62c1.

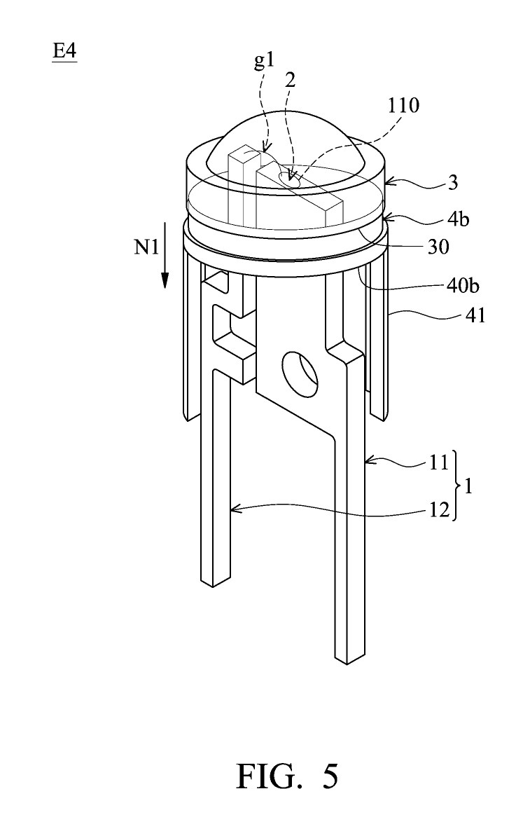

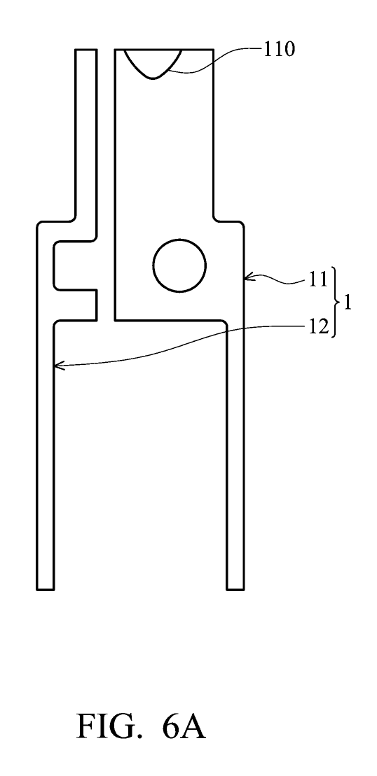

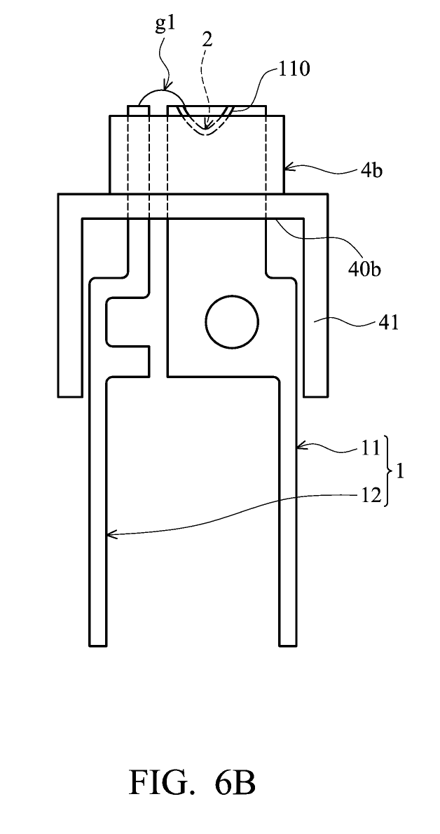

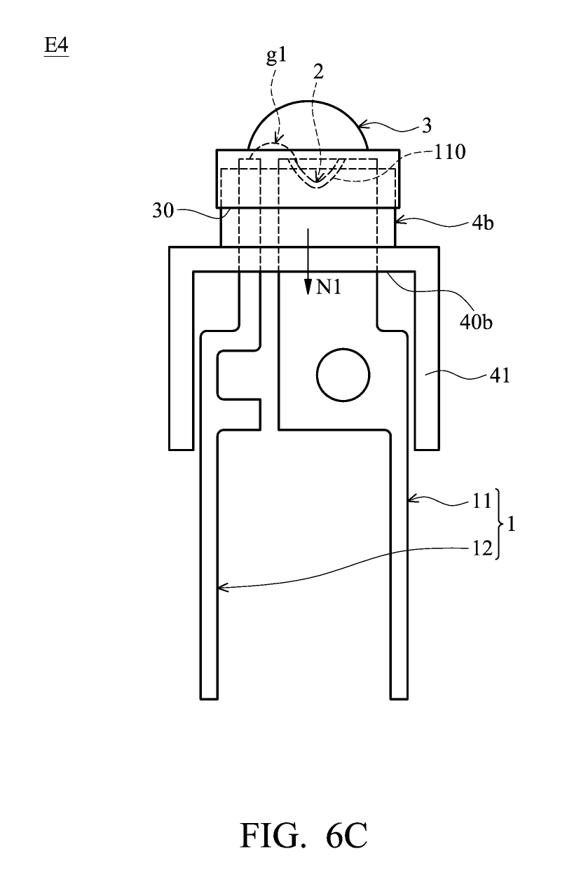

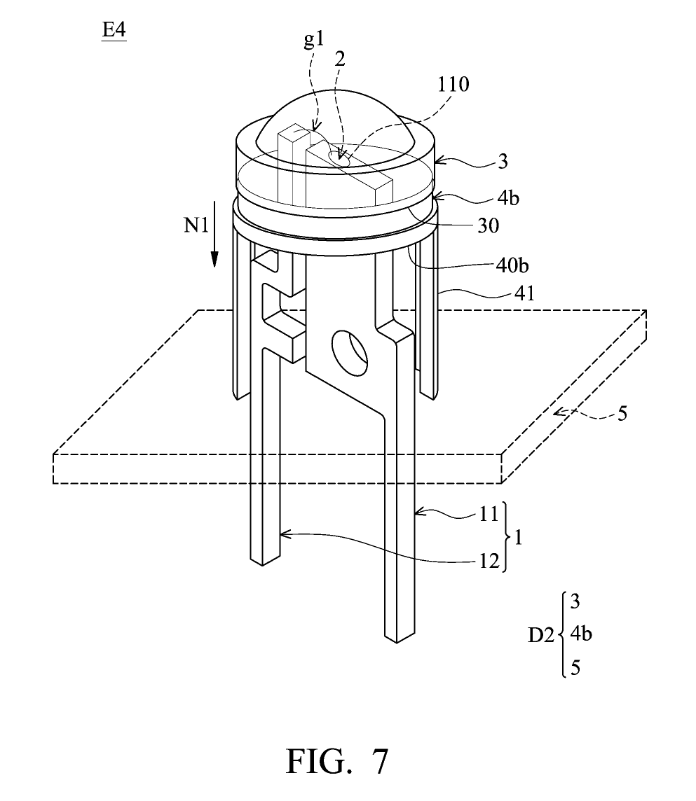

Referring to FIGS. 5, 6A to 6C and 7 simultaneously, FIG. 5 is a perspective view of a light emitting diode package structure E4 according to a fourth embodiment, FIGS. 6A to 6C are schematic views showing the formation of the light emitting diode package structure E4 of the fourth embodiment in each step of the manufacturing process, and FIG. 7 is another perspective view of the light emitting diode package structure E4.

The light emitting diode package structure E4 comprises a frame 1, a light emitting diode chip 2, an upper packing portion 3 having a sidewall 30, a lower packing portion 4b having a sidewall 40b, and a heat-dissipative element 5 (see FIG. 7), wherein the upper packing portion 3 and the lower packing portion 4b constitute a conductive structure D2. The frame 1, the light emitting diode chip 2, the upper packing portion 3 and the lead wire g1 are the same as those described in the first embodiment, and thus their description and relative relationship therebetween are not repeated here.

The light emitting diode package structure E4 of the fourth embodiment differs from the light emitting diode package structure E1 of the first embodiment in that the lower packing portion 4b of the light emitting diode package structure E4 further comprises two extensions 41 (e.g., pins or fins) extended from the sidewall 40b thereof and along a predetermined direction N1 to connect the heat-dissipative element 5 by locking, or it may be described that the extensions 41 of the lower packing portion 4b are extended opposite to or away from the upper packing portion 3 to connect the heat-dissipative element 5. Thus, heat generated from the light emitting diode chip 2 is transferred from the upper packing portion 3 and the extensions 41 of the lower packing portion 4a to the heat-dissipative element 5, thereby transferring the heat to an external mold (not shown in FIGs.).

The method for manufacturing the light emitting diode package structure E4 will be described in accompanying FIGS. 6A to 6C and 7, and the terms of the upper packing portion 3, the lower packing portion 4b and the heat-dissipative element 5 respectively represent “anti-fading unit 3”, “first heat-dissipative unit 4b”, “second heat-dissipative element 5” hereinafter. The method for manufacturing the light emitting diode package structure E4 comprises the following steps: providing the frame 1 with the first and second legs 11 and 12 (in FIG. 6A), providing the light emitting diode chip 2 to dispose on the first leg 11 of the frame 1 and to electrically couple to the second leg 12 of the frame 1, and providing the lead wire g1 to electrically couple between the light emitting diode chip 2 and the second leg 12 of the frame 1, and providing the first heat-dissipative unit 4b with the extensions 41 to cover and fix the first and second legs 11 and 12 of the frame 1 (in FIG. 6B); utilizing the anti-fading unit 3 to cover the light emitting diode chip 2 on the frame 1 and to partially cover the first heat-dissipative unit 4b, such that the light radiated from the light emitting diode chip 2 is outwardly emitted through the anti-fading unit 3 (in FIG. 6C); utilizing the extension 41 of the first heat-dissipative unit 4b to connect the second heat-dissipative element 5, such that the heat generated from the light emitting diode chip 2 is transferred to the second heat-dissipative element 5 by the guidance of the anti-fading unit 3 and the first heat-dissipative unit 4b to the lower packing portion 4a, i.e., the heat generated from the light emitting diode chip 2 is transferred from the anti-fading unit 3 to the first heat-dissipative unit 4b along the predetermined direction N1 (in FIG. 7).

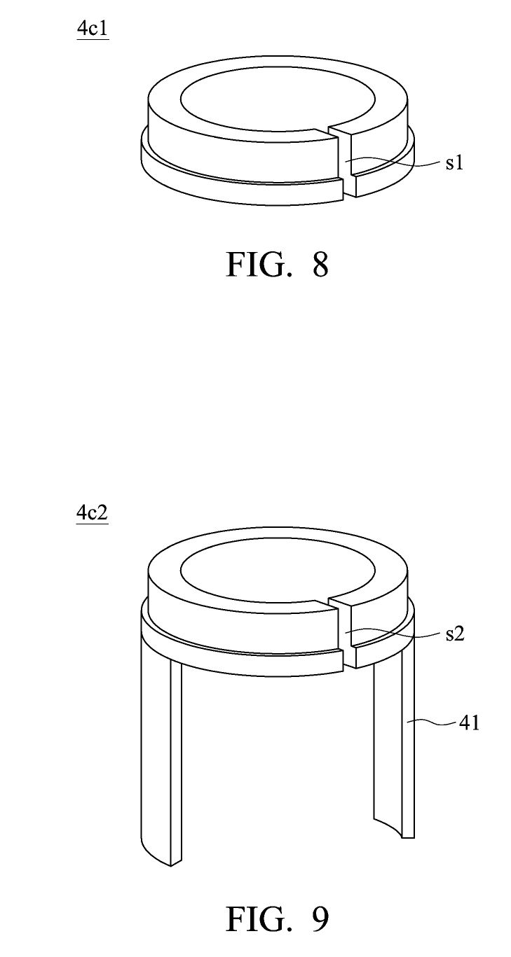

FIG. 8 is a schematic view of one lower packing portion (i.e., a heat-dissipative unit) 4c1. The lower packing portion 4c1 differs from the lower packing portion 4a of the light emitting diode package structure E1 of the first embodiment in that the lower packing portion 4c1, substantially a C-shaped structure provided with a slot s1, is detachably jacketed to the first and second legs 11 and 12 of the frame 1. Thus, the first and second legs 11 and 12 of the frame 1 can still be positioned by the C-shaped lower packing portion 4c1 when the C-shaped lower packing portion 4c1 is jacketed to the first and second legs 11 and 12 of the frame 1.

FIG. 9 is a schematic view of another lower packing portion (i.e., a heat-dissipative unit) 4c2. The lower packing portion 4c2 differs from the lower packing portion 4b of the light emitting diode package structure E4 of the fourth embodiment (as shown in FIG. 6B) in that the lower packing portion 4c2, substantially a C-shaped structure provided with a slot s2 that is detachably jacketed to the first and second legs 11 and 12 of the frame 1. Thus, the first and second legs 11 and 12 of the frame 1 can still be positioned by the C-shaped lower packing portion 4c2 when the C-shaped lower packing portion 4c2 is jacketed to the first and second legs 11 and 12 of the frame 1.

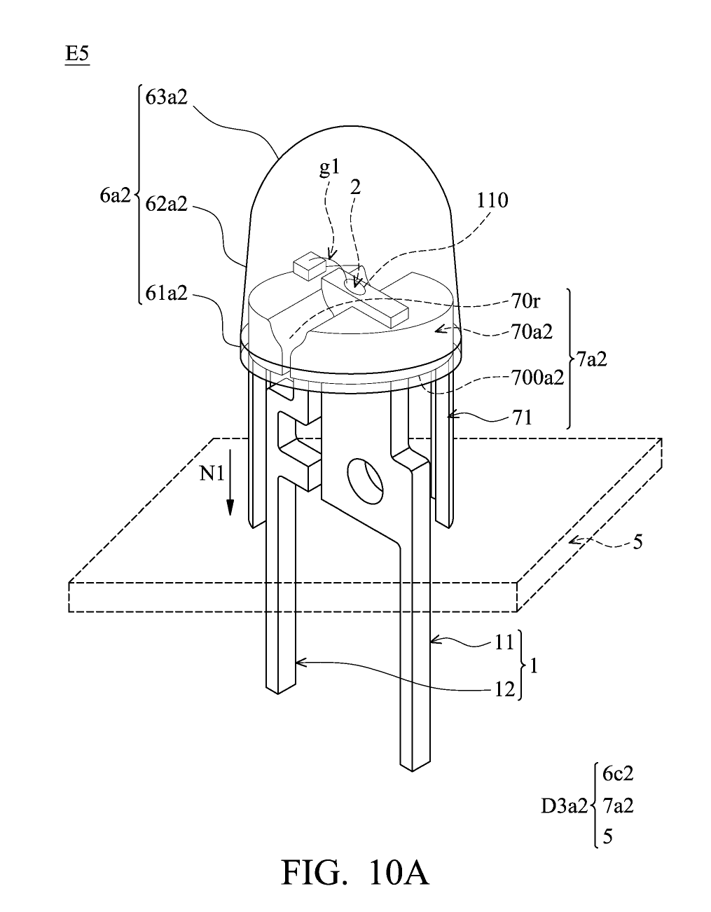

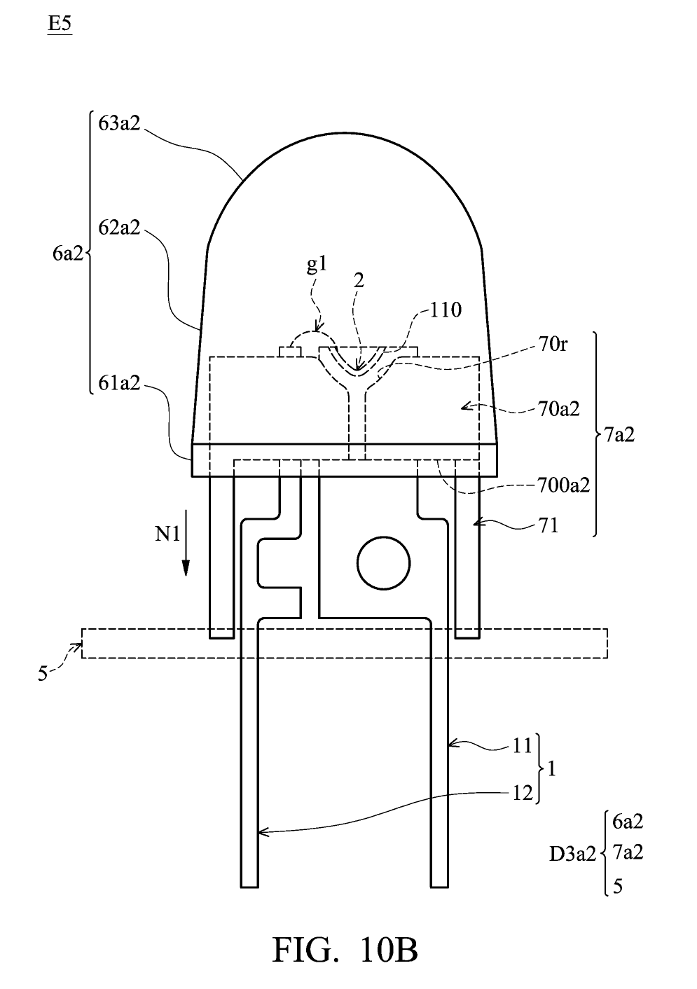

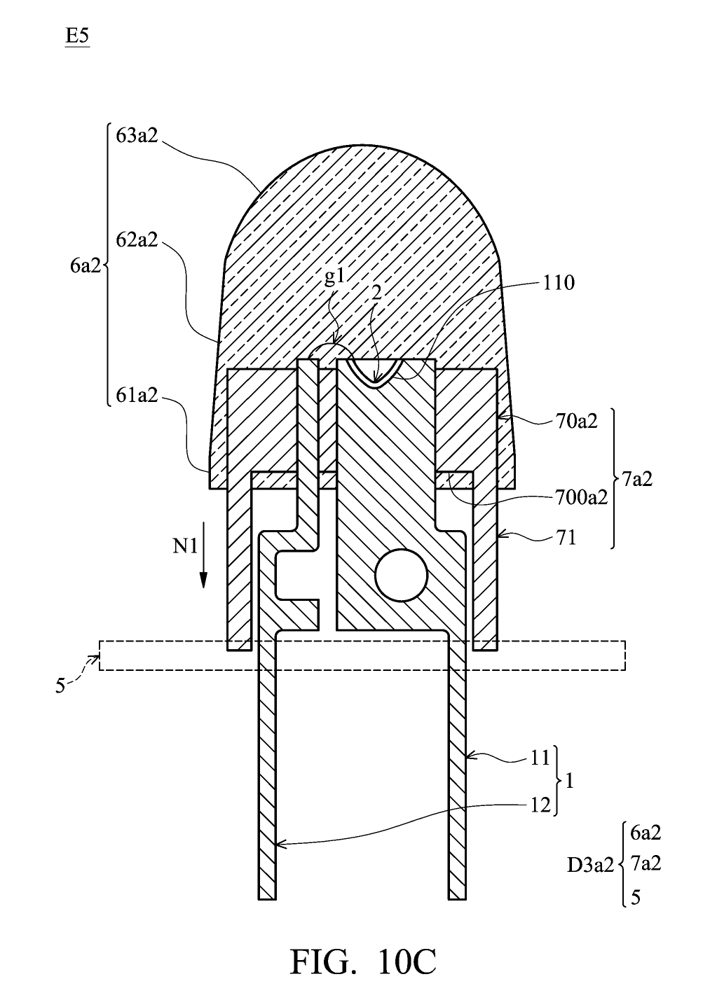

FIG. 10A is a perspective view of a light emitting diode package structure E5 according to a fifth embodiment, FIG. 10B is a side view of the light emitting diode package structure E5 of FIG. 10A, and FIG. 10C is a sectional view of the light emitting diode package structure E5 of FIG. 10A along a longitudinal direction (i.e., an extension direction of the frame 1) thereof.

In FIGS. 10A, 10B and 10C, the light emitting diode package structure E5 comprises a frame 1, a light emitting diode chip 2, an upper packing portion 6a2, a lower packing portion 7a2 and a heat-dissipative element 5, wherein the upper packing portion 6a2, the lower packing portion 7a2 and the heat-dissipative element 5 constitute a conductive structure D3a2. The frame 1, the light emitting diode chip 2 and the lead wire g1 are the same as those described in the first embodiment, and thus their description and relative relationship therebetween are not repeated here.

In the manufacturing process, the lower packing portion 7a2 is first to be disposed on the frame 1, and then the upper packing portion 6a2 fully covers the light emitting diode chip 2, the lead wire g1 and the lower packing portion 7a2.

The lower packing portion 7a2 is circumferentially disposed on the first and second legs 11 and 12 of the frame 1 by an injection molding, and the light emitting diode chip 2 is exposed by one surface of the lower packing portion 7a2. The lower packing portion 7a2 comprises a cylindrical body 70a2 having a side 700a2, a pair of two recesses 70r and two extensions 71, wherein the pair of two recesses 70r are disposed on the cylindrical body 70a2 and located at both sides of the light emitting diode chip 2, and the extensions 71 are extended from the side 700a2 of the cylindrical body 70a2 along a predetermined direction N1 (or it may be described that the extensions 71 of the lower packing portion 7a2 are extended opposite to or away from the upper packing portion 6a2) to connect to the heat-dissipative element 5. It is thus that the relative relationship and structural stability of the first and second legs 11 and 12 of the frame 1 can be increased by covering the lower packing portion 7a2 thereon.

The upper packing portion 6a2, formed by an injection molding, is utilized to cover the light emitting diode chip 2 and the lead wire g1 and to fully cover the cylindrical body 70a2 of the lower packing portion 7a2 but only partially cover the extensions 71. The upper packing portion 6a2 comprises a cylindrical part 61a2, a semi-sphere part 63a2 and a conical part 62a2 disposed between the cylindrical part 61a2 and the semi-sphere part 63a2.

Note that there is no clearance or gap formed between the molded assembled structure of the upper packing portion 6a2 and the lower packing portion 7a2, i.e., the light emitting diode chip 2 disposed on the first leg 11 of the frame 1 is fully covered by the upper packing portion 6a2 and the lower packing portion 7a2. Thus, the light radiated from the light emitting diode chip 2 is outwardly emitted through the upper packing portion 6a2, and the heat generated from the light emitting diode chip 2 is sequentially transferred from the lower packing portion 7a2 and the extensions 71 of the lower packing portion 7a2 to the heat-dissipative element 5.

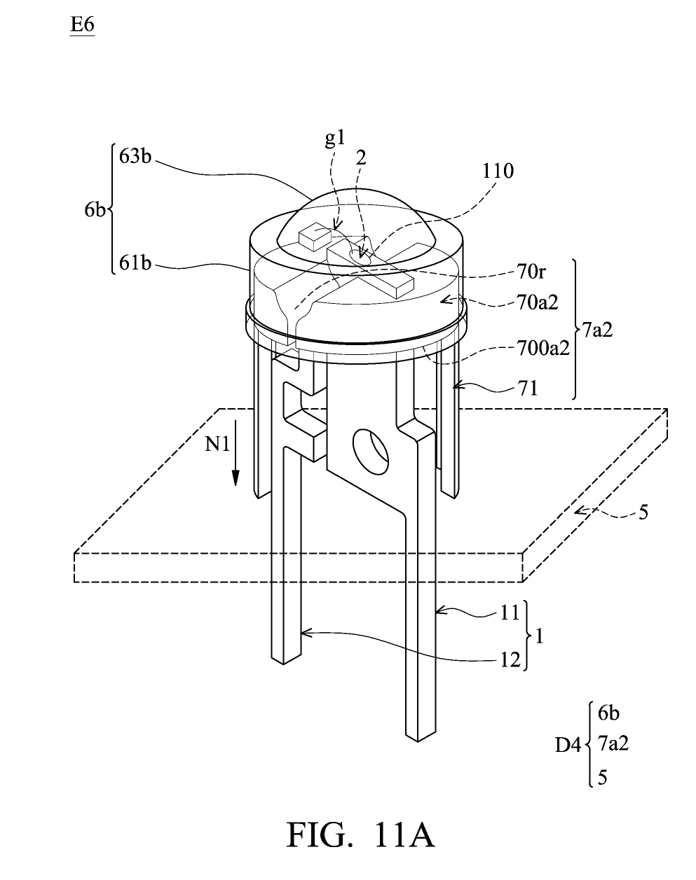

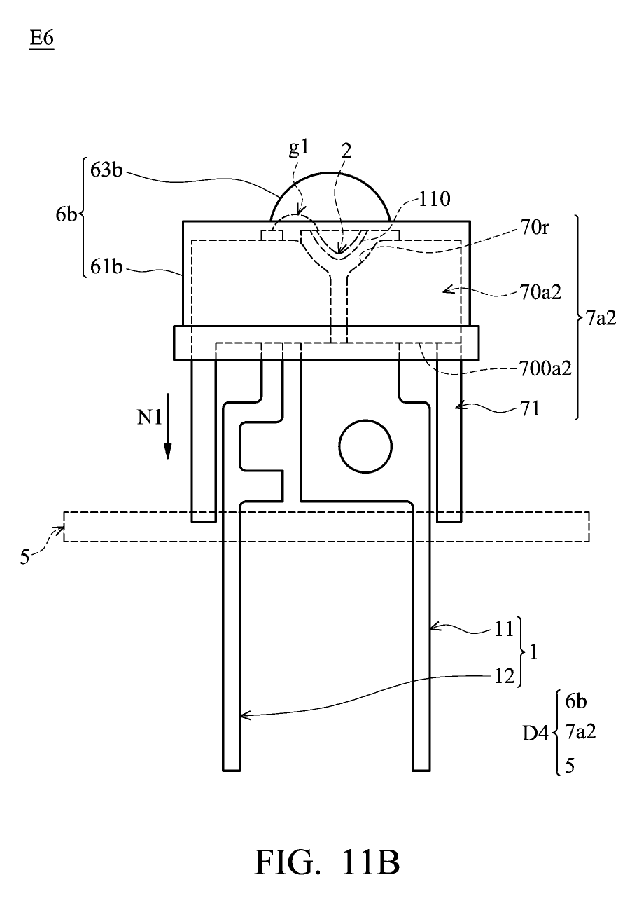

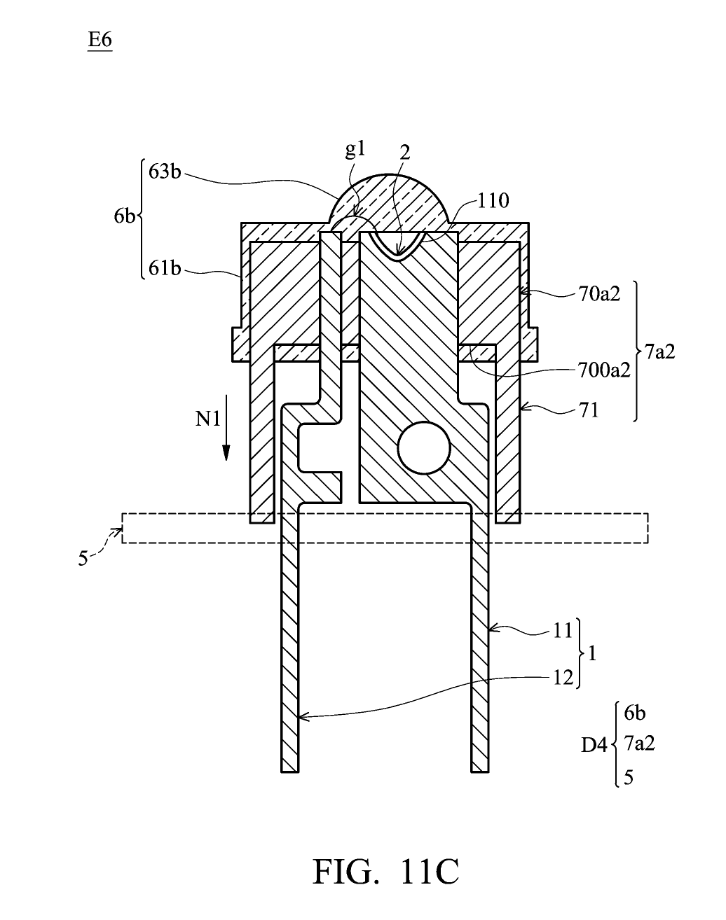

FIG. 11A is a perspective view of a light emitting diode package structure E6 according to a sixth embodiment, FIG. 11B is a side view of the light emitting diode package structure E6 of FIG. 11A, and FIG. 11C is a sectional view of the light emitting diode package structure E6 of FIG. 11A along a longitudinal direction (i.e., an extension direction of the frame 1) thereof.

In FIGS. 11A, 11B and 11C, the light emitting diode package structure E6 comprises a frame 1, a light emitting diode chip 2, an upper packing portion 6b, a lower packing portion 7a2 and a heat-dissipative element 5, wherein the upper packing portion 6b, the lower packing portion 7a2 and the heat-dissipative element 5 constitute a conductive structure D4. The frame 1, the light emitting diode chip 2, the lead wire g1, the lower packing portion 7a2 and the heat-dissipative element 5 are the same as those described in the fifth embodiment, and thus their description and relative relationship therebetween are not repeated here.

The light emitting diode package structure E6 of the sixth embodiment differs from the light emitting diode package structure E5 of the fifth embodiment in that the structure of the upper packing portion 6b is formed by a cylindrical part 61b and a semi-sphere part 63b, wherein the semi-sphere part 63b has a diameter less than that of the cylindrical part 61b, and the semi-sphere part 63b is corresponded to the light emitting diode chip 2.

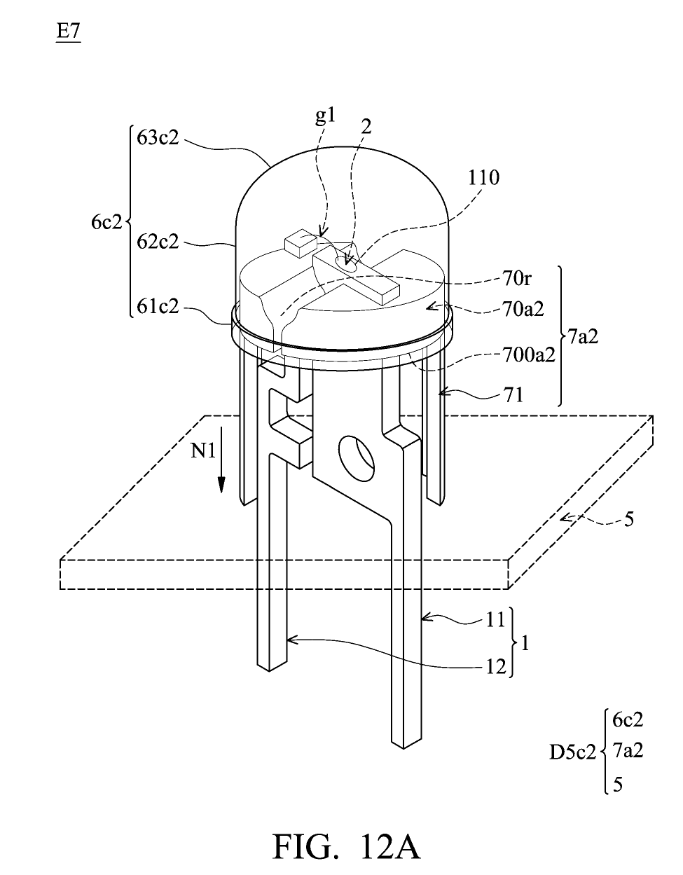

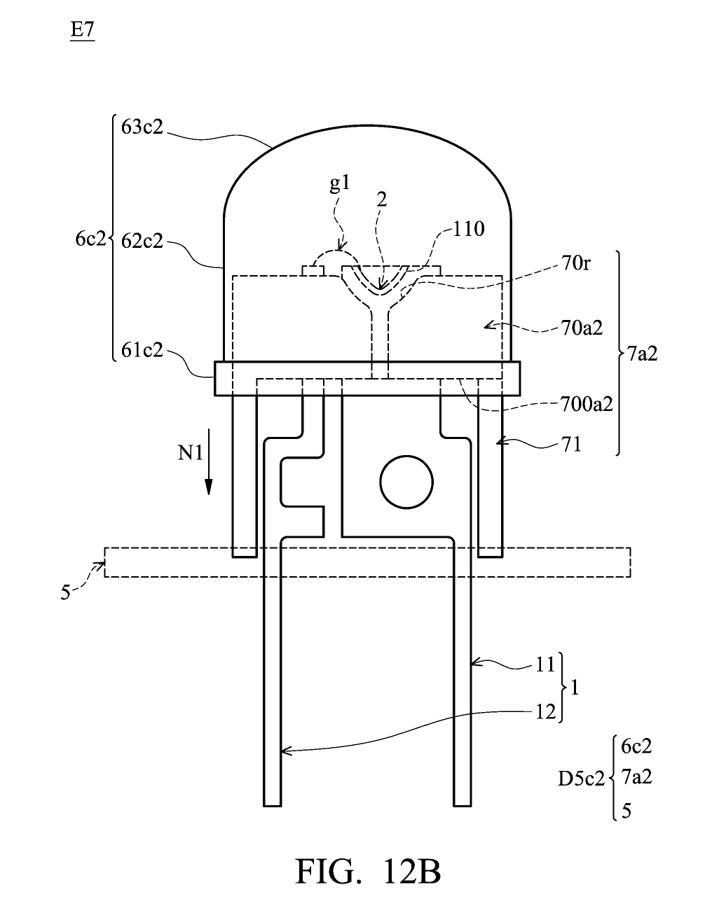

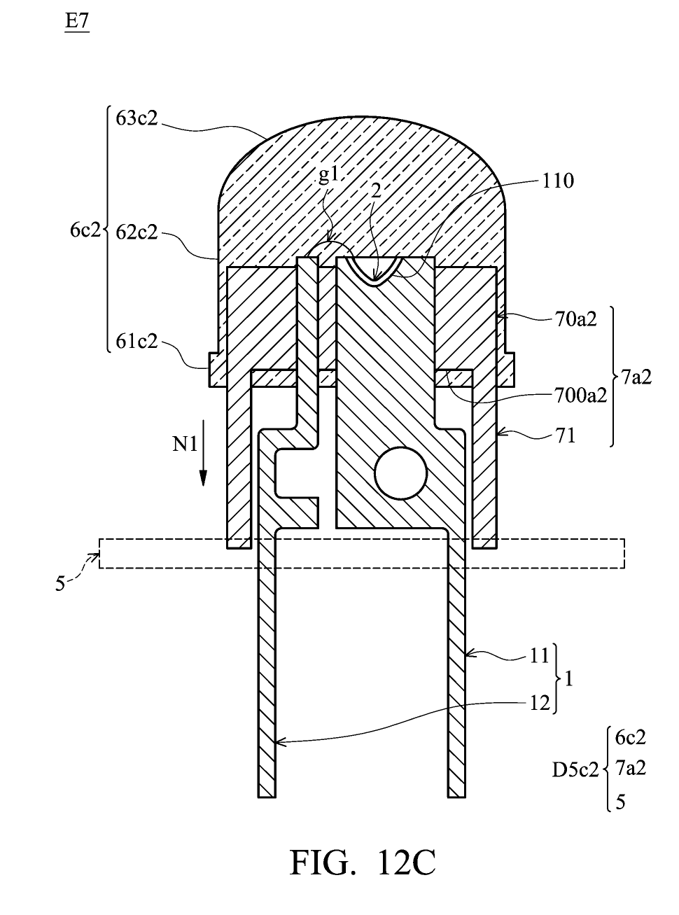

FIG. 12A is a perspective view of a light emitting diode package structure E7 according to a seventh embodiment, FIG. 12B is a side view of the light emitting diode package structure E7 of FIG. 12A, and FIG. 12C is a sectional view of the light emitting diode package structure E7 of FIG. 12A along a longitudinal direction (i.e., an extension direction of the frame 1) thereof.

In FIGS. 12A, 12B and 12C, the light emitting diode package structure E7 comprises a frame 1, a light emitting diode chip 2, an upper packing portion 6c2, a lower packing portion 7a2 and a heat-dissipative element 5, wherein the upper packing portion 6c2, the lower packing portion 7a2 and the heat-dissipative element 5 constitute a conductive structure D4. The frame 1, the light emitting diode chip 2, the lead wire g1, the lower packing portion 7a2 and the heat-dissipative element 5 are the same as those described in the fifth embodiment, and thus their description and relative relationship between are not repeated here.

The light emitting diode package structure E7 of the seventh embodiment differs from the light emitting diode package structure E5 of the fifth embodiment in that the structure of the upper packing portion 6c2 is formed by a first cylindrical part 61c2, a semi-sphere part 63c2 and a second cylindrical part 62c2 disposed between the first cylindrical part 61c2 and the semi-sphere part 63c2, and the first cylindrical part 61c2 has a diameter greater than that of the second cylindrical part 62c2.

Based on the described embodiments, the structural stability of the frame 1 is increased by deploying the lower packing portion next to the upper packing portion and a lesser silicone usage amount for the packing process can be obtained in comparison with the conventional arts. Thus, the cost for manufacturing the light emitting diode package structures can be reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting diode package structure, comprising:
a frame;
a light emitting diode chip electrically coupled to the frame;
an upper packing portion covering the light emitting diode chip on the frame, wherein light radiated from the light emitting diode chip is outwardly emitted through the upper packing portion; and
a lower packing portion circumferentially disposed on the frame and disposed next to the upper packing portion to secure the frame, wherein the lower packing portion is extended from and partially covered by the upper packing portion.

2. The light emitting diode package structure as claimed in claim 1, wherein the frame comprises a first leg and a second leg, the light emitting diode chip is disposed on the first leg of the frame and electrically coupled to the second leg of the frame, the upper packing portion is covering the light emitting diode chip disposed on the first leg and the second leg of the frame, and the lower packing portion is fixed at the first and second legs of the frame.

3. The light emitting diode package structure as claimed in claim 2 further comprising a supporting portion disposed on an end of the first leg of the frame, wherein the light emitting diode chip is disposed on the supporting portion.

4. The light emitting diode package structure as claimed in claim 3, wherein the end of the first leg of the frame is fixed at the supporting portion by a silver glue layer, and an end of the second leg of the frame is electrically coupled to the light emitting diode chip by a lead wire.

5. The light emitting diode package structure as claimed in claim 3, wherein the end of the second leg of the frame is electrically coupled to the light emitting diode chip by an eutectic reaction.

6. The light emitting diode package structure as claimed in claim 2, wherein the first and second legs of the frame are downwardly extended and arranged in parallel.

7. The light emitting diode package structure as claimed in claim 1, wherein the upper packing portion and the lower packing portion are partially overlapped to each other.

8. The light emitting diode package structure as claimed in claim 1, wherein the upper packing portion comprises an anti-fading material, and the lower packing portion comprises a heat-dissipative material.

9. The light emitting diode package structure as claimed in claim 8, wherein the anti-fading material is selected from the group of epoxy, methyl rubber, methyl resin, benzene ring resin, organic denature silicon and the combination thereof.

10. The light emitting diode package structure as claimed in claim 8, wherein the heat-dissipative material is selected from the group of poly para-phenylenediacyl para-phenylenediamine, high temperature nylon, liquid crystalline resin, Polyetheretherketone, resin containing silicon, polyamide-imide resin, ceramic and the combination thereof.

11. The light emitting diode package structure as claimed in claim 1, wherein the lower packing portion comprises at least one extension oppositely extended relative to the upper packing portion.

12. The light emitting diode package structure as claimed in claim 1 further comprising a heat-dissipative element, and the lower packing portion comprises at least one extension connected to the heat-dissipative element, such that the heat generated from the light emitting diode chip is transferred to the heat-dissipative element via the upper packing portion and the at least one extension of the lower packing portion.

13. The light emitting diode package structure as claimed in claim 1, wherein the lower packing portion is integrally formed with the frame.

14. The light emitting diode package structure as claimed in claim 1, wherein the lower packing portion substantially comprises a C-shaped structure.

15. A conductive structure for dissipating heat generated from a light emitting diode chip, comprising:
an upper packing portion covering the light emitting diode chip; and
a lower packing portion disposed next to the upper packing portion, wherein the light emitting diode chip is electrically coupled to a frame, such that the heat generated from the light emitting diode chip is transferred to the lower packing portion via the frame.

16. The conductive structure as claimed in claim 15, wherein the upper packing portion comprises an anti-fading material and the lower packing portion comprises a heat-dissipative material.

17. The conductive structure as claimed in claim 15, wherein the lower packing portion comprises at least one extension oppositely extended relative to the upper packing portion.

18. The conductive structure as claimed in claim 15 further comprising a heat-dissipative element, and the lower packing portion comprises at least one extension connected to the heat-dissipative element, such that the heat generated from the light emitting diode chip is transferred to the heat-dissipative element via the upper packing portion and the at least one extension of the lower packing portion.

19. A method for manufacturing a light emitting diode package structure, comprising the steps of:
providing a frame comprising a first leg and a second leg;
providing a light emitting diode chip to dispose on the first leg of the frame and electrically couple to the second leg of the frame;
utilizing a first heat-dissipative unit to cover and secure the first and second legs of the frame; and
utilizing an anti-fading unit to cover the light emitting diode chip on the frame and to partially cover the first heat-dissipative unit, such that light emitting from the light emitting diode chip is outwardly radiated via the anti-fading unit, and heat generated from the light emitting diode chip is transferred to the first heat-dissipative unit via the anti-fading unit.

20. The method as claimed in claim 19 further providing a lead wire to electrically couple between the light emitting diode chip disposed on the first leg of the frame and the second leg of the frame.

21. The method as claimed in claim 19 further providing a second heat-dissipative unit to connect to at least one extension of the first heat-dissipative unit, such that the heat generated from the light emitting diode chip is transferred to the second heat-dissipative element via the anti-fading unit and the first heat-dissipative unit.

22. A light emitting diode package structure, comprising:
a frame;
a light emitting diode chip electrically coupled to the frame;
a lower packing portion disposed on the frame, comprising a body and at least one extension connected to the body; and
an upper packing portion covering the light emitting diode chip, to fully cover the body of the lower packing portion, and to partially cover the at least one extension of the lower packing portion.

23. The light emitting diode package structure as claimed in claim 22, wherein the upper packing portion comprises a cylindrical part, a semi-sphere part and a conical part disposed between the cylindrical part and the semi-sphere part.

24. The light emitting diode package structure as claimed in claim 22, wherein the upper packing portion comprises a cylindrical part and a semi-sphere part, and a diameter of the semi-sphere part is less than that of the cylindrical part.

25. The light emitting diode package structure as claimed in claim 22, wherein the upper packing portion comprises a first cylindrical part, a semi-sphere part and a second cylindrical part disposed between the first cylindrical part and the semi-sphere part.

26. The light emitting diode package structure as claimed in claim 22, wherein the frame comprises a first leg and a second leg, the light emitting diode chip is disposed on the first leg of the frame and electrically coupled to the second leg of the frame, and the upper packing portion is disposed on the first and second legs of the frame.

27. The light emitting diode package structure as claimed in claim 26 further comprising a lead wire electrically coupled between the light emitting diode chip disposed on the first leg of the frame and the second leg of the frame.

28. The light emitting diode package structure as claimed in claim 27, wherein the lead wire comprises a metallic wire.

29. The light emitting diode package structure as claimed in claim 22, wherein the upper packing portion comprises an anti-fading material, and the lower packing portion comprises a heat-dissipative material.

30. The conductive structure as claimed in claim 22 further comprising a heat-dissipative element connected to the at least one extension of the lower packing portion.
